(19) United States
(12) Patent Application Publication
(10) Pub. No.: US 2026/0173849 A1
(43) Pub. Date: Jun. 18, 2026

(54) METHODS FOR MANUFACTURING SEMICONDUCTOR PLUG STRUCTURE AND SEMICONDUCTOR STRUCTURE HAVING THE SEMICONDUCTOR PLUG STRUCTURE

(71) Applicant: TAIWAN SEMICONDUCTOR MANUFACTURING COMPANY LTD., HSINCHU (TW)

(72) Inventors: YU-HUNG CHENG, TAINAN CITY (TW); KUAN-LIANG LIU, PINGTUNG COUNTY (TW); CHING I LI, TAINAN (TW)

(21) Appl. No.: 18/977,998

(22) Filed: Dec. 12, 2024

(51) Int. Cl. H01L 23/528; H01L 21/768; H01L 23/532

(52) U.S. Cl. CPC H10W 20/435; H10W 20/035; H10W 20/056; H10W 20/062; H10W 20/4451

(57) ABSTRACT

A method for manufacturing a semiconductor plug structure in a semiconductor structure is provided. The method includes the operations as follows. A substrate is received. A trench is formed at a side of the substrate. The trench is filled with a polysilicon material. Rounds of deposition-anneal operations are terminated when the polysilicon material closes an upper portion of the trench. Filling the trench includes performing a plurality of rounds of deposition-anneal operations, and each round including depositing the polysilicon material in the trench under a deposition temperature and annealing the polysilicon material under an annealing temperature. A semiconductor structure having the semiconductor plug is also provided.

### BACKGROUND

A bipolar-CMOS (complementary metal oxide semiconductor)-DMOS (double diffused metal oxide semiconductor) (BCD) process, which integrates bipolar, CMOS, and DMOS devices in one semiconductor chip, has been widely used to make power devices, such as a high voltage electrical device. There is a continuous need to further optimize the BCD process for improving the electrical performance of the power devices.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a flow diagram illustrating a method for manufacturing a semiconductor plug structure in a semiconductor structure according to some embodiments of the present disclosure.

FIGS. 2A-2E illustrate cross-sectional views of a process in preparing a semiconductor structure according to some embodiments of the present disclosure.

FIG. 3A illustrates a graph showing the changes in time and temperature during the trench filling process according to some embodiments of the present disclosure.

FIGS. 3B and 3C illustrate an example of the reflow of the surface of a silicon material by an annealing process.

FIGS. 4A-4G illustrate cross-sectional views of a process in forming a stack of polysilicon material in a deep trench according to some embodiments of the present disclosure.

FIG. 5 illustrates a graph showing the changes in time and temperature during the trench filling process according to some embodiments of the present disclosure.

FIG. 6 illustrates a graph showing the changes in time and temperature during the trench filling process according to some embodiments of the present disclosure.

FIG. 7A illustrates a flow diagram illustrating a method for manufacturing a semiconductor plug structure in a substrate structure according to some embodiments of the present disclosure.

FIG. 7B illustrates a graph showing the changes in time and temperature during the trench filling process according to some embodiments of the present disclosure.

FIG. 8 illustrates a graph showing the changes in time and temperature during the trench filling process according to some embodiments of the present disclosure.

FIGS. 9A-9E illustrate cross-sectional views of a process in forming a contact structure over a semiconductor plug structure according to some embodiments of the present disclosure.

FIG. 10 illustrates a cross-sectional view of a semiconductor structure manufactured by the method disclosed in some embodiments of the present disclosure.

FIG. 11 illustrates a cross-sectional view of a semiconductor structure manufactured by the method disclosed in some embodiments of the present disclosure.

FIG. 12 illustrates a cross-sectional view of a semiconductor structure manufactured by the method disclosed in some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

Power metal-oxide-semiconductor field-effect transistors (power MOSFETs) are components in modern power electronics that widely used across various industries. These devices can be implemented using different semiconductor technologies, including bipolar, complementary metal-oxide-semiconductor (CMOS), and diffusion metal-oxide-semiconductor (DMOS) structures. A specific class of such devices is the Bipolar-CMOS-DMOS (BCD) device, which leverages the combined benefits of these three technologies—bipolar transistors for high current driving capability, CMOS for logic and control functions, and DMOS for efficient power handling. BCD technology is particularly suitable for applications requiring both digital logic and analog power components on a single chip, such as in automotive electronics and power management integrated circuits. Among the various power transistors in BCD devices, lateral diffused metal-oxide-semiconductor (LDMOS) transistors are frequently employed due to their superior performance in handling high voltages and currents. LDMOS transistors, with their lateral current flow and effective use of diffused regions for voltage control, offer low on-resistance and high breakdown voltage, making them highly desirable in power electronics applications.

A typical BCD device structure includes several layers and regions, used to ensure optimal performance across both power and logic domains. The BCD device is built on a semiconductor substrate, which serves as the foundation for various structures that isolate and protect the different functional areas. Some examples of isolation structures include the shallow trench isolation (STI) and deep trench isolation (DTI) structures, which prevent unwanted electrical interference between different regions of the device. The STI structure, typically formed in a first portion of the semiconductor substrate, creates a physical barrier that limits electrical crosstalk between neighboring transistor cells, improving overall device reliability. In contrast, the DTI structure, which provides additional isolation to deeper regions of the device, is positioned within the STI structure and extends into a second portion of the substrate, penetrating deeper into the material. This complex isolation strategy is essential for ensuring that high-voltage and high-current areas of the device are effectively separated from low-voltage regions, thereby reducing parasitic capacitance and improving overall device reliability.

In some examples, the manufacturing process for a BCD device involves multiple precision etching steps, ensuring that the different materials used for the device layers are accurately shaped and positioned. For instance, initially, a conductive layer, such as polysilicon plug, is surrounded by the DTI structure. This conductive layer is etched back using dry etching techniques, which offer high anisotropy and precision in shaping the trench. Following this, an isolation layer, often composed of a dielectric oxide material, is applied to insulate the conductive elements. Wet etching is employed to selectively etch back the isolation layer, a process that typically provides greater control over the removal of material from the trench, ensuring proper formation of the isolation regions. Ideally, performing these operations may result in a reliable BCD device capable of withstanding the high voltages and currents typically encountered in power electronics.

However, in some real practice, a seam or void may be included in DTI structure or the plug in a deep trench. These seam or void within a plug is an unwanted defect that commonly occurs during the semiconductor manufacturing process.

To be more detailed, one of the main causes of void formation is incomplete filling during the deposition of material. Techniques such as chemical vapor deposition (CVD) or high-density plasma CVD are commonly used to deposit materials into the trench. However, when deposition is not well-controlled, particularly in deep or narrow trenches, the material may fail to completely fill the trench. This can leave gaps or voids, especially in areas where the trench geometry becomes more complex or narrows towards the bottom. Another common cause of voids is non-uniform etching during the trench formation process. For instance, if the etching process does not proceed uniformly, it may result in irregular trench profiles. These irregularities make it more challenging for the material to fill the trench completely during the subsequent deposition process, often leading to the formation of seams along the trench walls or voids at the bottom of the trench, particularly in deep trenches where the etching process becomes more difficult to control.

The presence of seams and voids in a plug structure in the deep trench poses risks to the performance and reliability of the semiconductor device. In some comparative approaches, voids and seams can compromise properties of the plug structure in the deep trench.

Moreover, since the semiconductor substrate with the plug structure in the deep trench can be further planarized (e.g., through CMP) for subsequent manufacturing operations, if a seam or void is in close proximity to the upper end of the plug structure, it may be exposed after the planarization process. As a result, a smaller trench may appear at the top of the plug structure, potentially affecting features such as a contact formed over the plug structure. In other words, the seam (or void) in the plug structure in the deep trench could lead to a “contact open” issue if it is exposed during subsequent manufacturing operations.

Therefore, some embodiments of the present disclosure aim to provide methods for manufacturing plug structures in deep trench. In some embodiments, when the plug structure in a semiconductor includes a seam, the distance between an upper end (or called top end) of the plug structure and an upper end of the seam should be sufficient to ensure that the seam is not exposed or revealed during subsequent manufacturing operations. In other words, in some embodiments, the depth of the seam within the plug structure, if present, can be controlled to be deep enough so as not to affect the formation of other structures.

In some embodiments of the present disclosure, the plug structure is part of an LDMOS device. In some embodiments, the LDMOS device is fabricated using the Bipolar-CMOS-DMOS (BCD) process on silicon-on-insulator (SOI) substrates, referred to as an SOI-LDMOS device. This type of device has a strong ability to sustain high drain voltages while minimizing power leakage, achieving high operational speeds, and offering radiation resistance. The plug structure may comprise polysilicon material, and such Poly_DTI isolation for high-voltage SOI-based devices can be implemented as a polysilicon plug design for grounding in power IC applications.

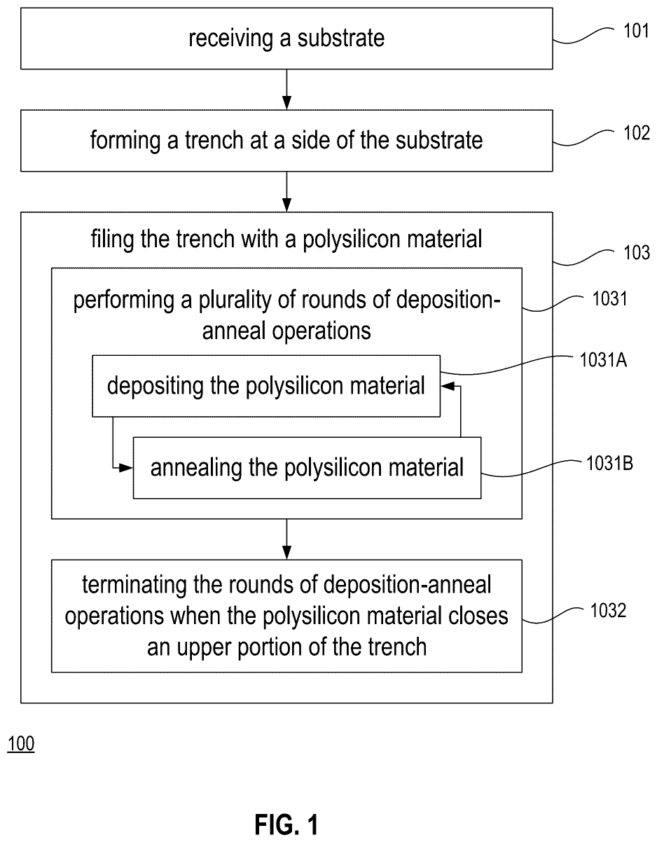

FIG. 1 is a flow diagram illustrating a method 100 for manufacturing a semiconductor plug structure in a semiconductor structure. The semiconductor plug structure can be a polysilicon plug that based on a deep trench isolation (DTI) structure (e.g., penetrating a DTI structure) allowing for conductive pass-through connections in a semiconductor substrate. In some embodiments, the method includes: an operation 101: receiving a substrate; an operation 102:
forming a trench at a side of the substrate; and an operation 103: filling the trench with a polysilicon material. In filling the trench with the polysilicon material, it may include: an operation 1031: performing a plurality of rounds of deposition-anneal operations; and an operation 1032: terminating the rounds of deposition-anneal operations when the polysilicon material closes an upper portion of the trench. In some embodiments, each round of deposition-anneal operations includes: an operation 1031A: depositing the polysilicon material in the trench under a deposition temperature; and an operation 1031B: annealing the polysilicon material under an annealing temperature.

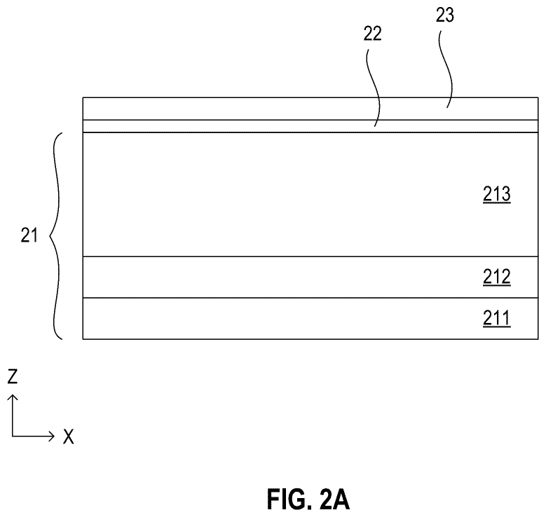

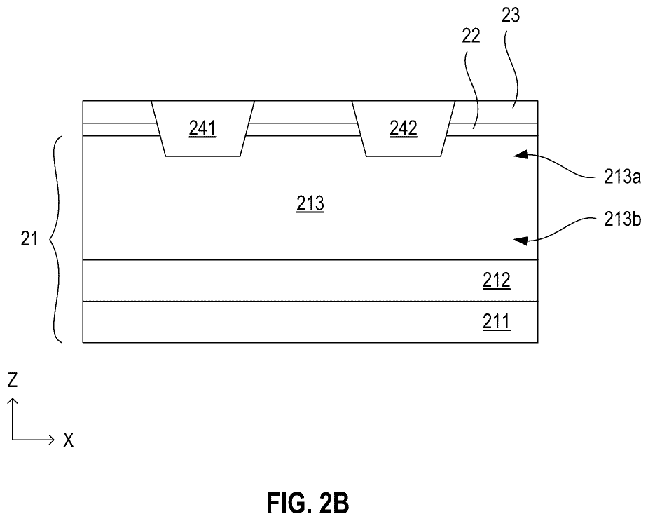

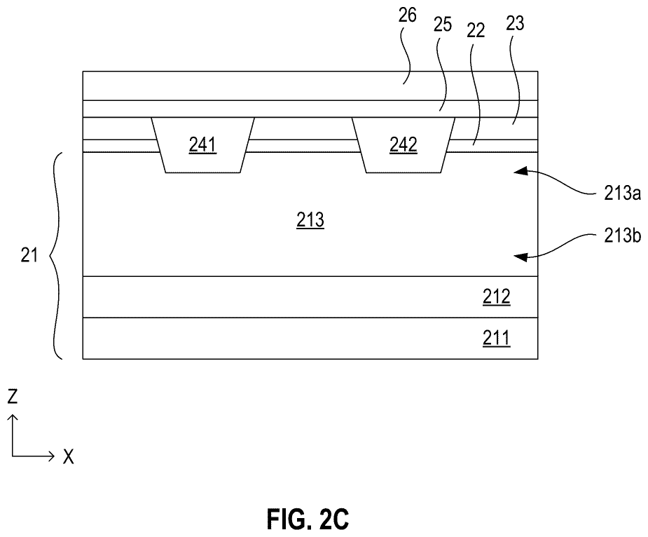

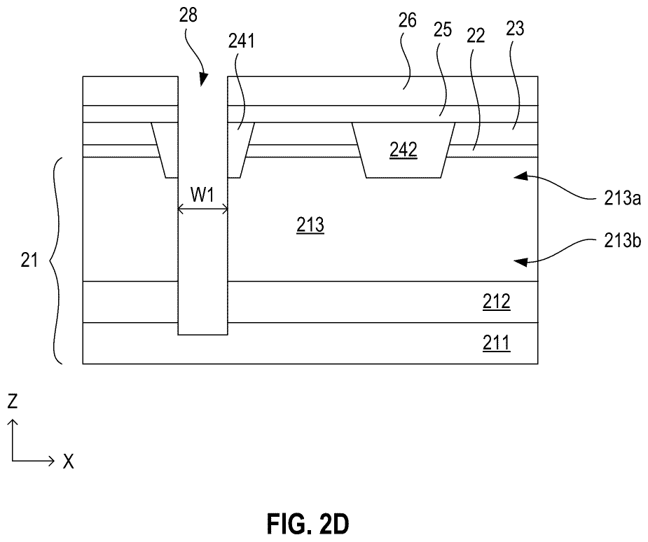

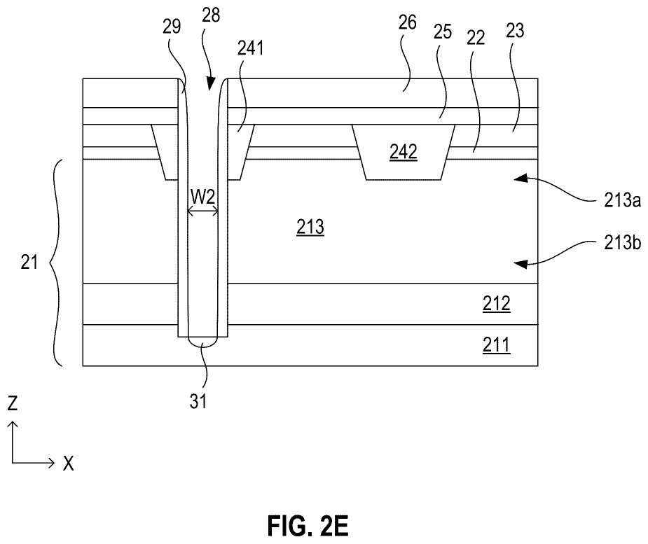

Referring to FIGS. 1 and 2A to 2C, the substrate received in the operation 101 may include the structures illustrated in FIGS. 2A to 2C. That is, in some embodiments, beginning from the disclosure in FIG. 2A, a pad oxide layer 22 and a first nitride layer 23 are sequentially formed on a semiconductor substrate 21. The semiconductor substrate 21 may include a lower semiconductor layer 211, a buried insulation layer 212 (e.g., a buried oxide layer (BOX)), and an upper semiconductor layer 213. In some embodiments, the semiconductor substrate 21 may be, for example, a part of a silicon-on-insulator (SOI) substrate, a SOS (silicon-on-sapphire) substrate, or other suitable substrates. In some embodiments, the lower semiconductor layer 211 may be an elemental semiconductor or a compound semiconductor. The elemental semiconductor may be composed of single species of atoms, such as silicon (Si) and germanium (Ge) or other suitable materials. The compound semiconductor may be composed of two or more elements, such as silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or other suitable materials. The buried insulation layer 212 between the lower semiconductor layer 211 and the upper semiconductor layer 213 may be formed by, for example, but not limited to, SOI techniques, such as implanted oxygen techniques (SIMOX), bonded-and-etch-back techniques (BESOI), or other suitable techniques. In some embodiments, the buried insulation layer 212 may be made of, for example, silicon oxide, or other suitable oxide materials. In some embodiments, the upper semiconductor layer 213 and the lower semiconductor layer 211 may be made of the same material. The pad oxide layer 22 is formed over the upper semiconductor layer 213 opposite to the buried insulation layer 212. In some embodiments, the pad oxide layer 22 is formed using, for example, chemical vapor deposition (CND), physical vapor deposition (PVD), atomic layer deposition (ALD), or other suitable deposition techniques. In alternative embodiments, the pad oxide layer 22 may be formed by thermally oxidizing the upper semiconductor layer 213 in an oxygen-containing atmosphere. The pad oxide layer 22 may include silicon oxide. Other suitable materials for the pad oxide layer 22 are within the contemplated scope of the present disclosure. The first nitride layer 23 is formed over the pad oxide layer 22 opposite to the upper semiconductor layer 213 using, for example, CVD, PVD, ALD, or other suitable deposition techniques. The first nitride layer 23 may include silicon nitride. Other suitable materials for the first nitride layer 23 are within the contemplated scope of the present disclosure.

The buried insulation layer 212 may have a thickness as about 0.3 μm, the upper semiconductor layer 213 may have a thickness as about 7 μm, less than about 20 μm, or less than about 40 μm. The first nitride layer 23 may have a thickness as about 0.08 μm, but other values or range values are also within the scope of the disclosure.

Referring to FIG. 2B, in some embodiments, a first and a second STI structures 241, 242 are formed in the structure shown in FIG. 2A and are spaced apart from each other. In some embodiments, the first and the second STI structures 241, 242 are located at a first substrate portion 213a of the semiconductor substrate 21. In some embodiments, the upper semiconductor layer 213 may include the first substrate portion 213a which has a top surface of the upper semiconductor layer 213. In some embodiments, forming the STI structures include (i) forming a patterned mask (not shown) on the first nitride layer 23 shown in FIG. 2A to partially expose the first nitride layer 23, (ii) etching the first nitride layer 23, the pad oxide layer 22, and the first substrate portion 213a of the upper semiconductor layer 213 through the patterned mask to form shallow trenches (not shown), (iii) filling the shallow trenches with an oxide material, for example, silicon dioxide or other suitable oxide materials, and (iv) removing an excess of the oxide material on the etched first nitride layer 23 using, for example, CMP or other suitable techniques. The patterned mask may include a photoresist material or other suitable mask materials, and may be formed by coating a photoresist layer, soft-baking, exposing the photoresist layer through a photomask, post-exposure baking, and developing the photoresist layer, followed by hard-baking to thereby obtain the patterned mask.

Referring to FIG. 2C, in some embodiments, a second nitride layer 25, and a dielectric layer 26 are sequentially formed on the structure shown in FIG. 2B. The second nitride layer 25 is formed on the etched first nitride layer 23 and the first and the second STI structures 241, 242 using, for example, CVD, PVD, ALD, or other suitable deposition techniques. The second nitride layer 25 may include silicon nitride. Other suitable materials for the second nitride layer 25 are within the contemplated scope of the present disclosure. The second nitride layer 25 may have a thickness greater than that of the first nitride layer 23, such as about 0.16 μm, but other values or range values are also within the scope of the disclosure. The dielectric layer 26 is formed on the second nitride layer 25 opposite to the etched first nitride layer 23 using, for example, CVD, PVD, ALD, or other suitable deposition techniques. The dielectric layer 26 may include undoped silicate glass (USG). Other suitable dielectric materials for the dielectric layer 26 are within the contemplated scope of the present disclosure. The dielectric layer 26 may have a thickness as about 0.6 μm, but other values or range values are also within the scope of the disclosure.

Referring to FIG. 2D, in some embodiments, the dielectric layer 26, the second nitride layer 25, the first STI structure 241, the upper semiconductor layer 213, the buried insulation layer 212, and the lower semiconductor layer 211 are etched and patterned through a patterned mask (not shown) to form a deep trench 28. In this operation, the deep trench 28 extends through the dielectric layer 26, the second nitride layer 25, the first STI structure 241, a second substrate portion 213b of the upper semiconductor layer 213, and the buried insulation layer 212, into the lower semiconductor layer 211. Forming the deep trench 28 may be performed using, for example, wet etching, dry etching, a combination thereof, or other suitable etching techniques. After the formation of the deep trench 28, the patterned mask may be removed.

Referring to FIG. 2E, an insulating material layer 29 is formed on two opposite trench-defining sidewalk of the deep trench 28. Forming the insulating material layer 29 may include (i) conformally depositing an insulating material for the insulating material layer 29 over the structure shown in FIG. 2D using, for example, CND, PVD, or other suitable deposition techniques, and (ii) anisotropically etching (e.g., dry etching, wet etching, a combination thereof, or other suitable etching techniques) the insulating material to remove the insulating material on the patterned dielectric layer 26 and a bottom surface of the deep trench 28 to thereby form the insulating material layer 29 on the two opposite trench-defining sidewalls of the deep trench 28. The insulating material layer 29 may include silicon oxide, or silicon oxynitride. Other suitable materials for the insulating material layer 29 are within the contemplated scope of the present disclosure. In some embodiments, the dielectric layer 26 underlying the insulating material may also be etched back. In some embodiments, a width W1 of the deep trench 28 is about 1 μm. In some embodiments, a width W2 as defined by the insulating material layer 29 occupying the deep trench 28 is about 0.5 μm.

In some embodiments, a doping region 31 may be formed in the lower semiconductor layer 211 using, for example, ion implantation or other suitable doping techniques to enhance electrical connection between a polysilicon material 27 laterally surrounded by a DTI structure 30 (e.g., shown in FIG. 10) and the lower semiconductor layer 211.

Subsequently, a polysilicon layer can be formed over the structure shown in FIG. 2E to cover the fill the deep trench 28. The polysilicon material can be deposited through low-pressure chemical vapor deposition (LDCVD) process, but other suitable deposition techniques is still possible to be used.

In some comparative embodiments, the precursor used in depositing the polysilicon material is dichlorosilane (DCS), with the chemical formula SiH₂Cl₂. In the case that DCS is used in LPCVD process, DCS is introduced into the reactor (e.g., in a RP-EPI tool) along with a carrier gas, such as hydrogen (H₂), at elevated temperatures. Upon decomposition, DCS releases silicon atoms, which then deposit as polysilicon on the surface of the wafer. In some examples, the deposition temperature is about 850° C., depending on the desired deposition rate and film characteristics. However, the grain size of the polysilicon formed by using DCS as precursor would induce a high surface roughness during polysilicon is merged, and therefore voids are easily formed between two opposite surfaces of polysilicon in the deep trench 28. In some examples, a void size can be about 100 nm when DCS is used.

In other comparative embodiments, the precursor used in depositing the polysilicon material is disilane (Si₂H₆). In some examples, the deposition temperature is around 520° C. when Si₂H₆ is used as a precursor, which is much lower than the deposition temperature used with DCS. Compared to the DCS-based precursor, the issue of high surface roughness-induced voids is relatively lower when using the Si₂H₆-based precursor. However, the seam depth of the polysilicon in the deep trench 28 is usually located at a higher position (i.e., near the upper end of the deep trench 28) because the surface migration ability of polysilicon with the Si₂H₆-based precursor is relatively poor. As a result, polysilicon tends to accumulate at the opening of the deep trench 28 and closes the upper portion of the trench in shortly.

In some embodiments of the present disclosure, the precursor used in depositing the polysilicon material is SiH₄. In some examples, the deposition temperature is around 700° C. (e.g., in a range from about 650° C. to about 750° C.) when SiH4 is used as a precursor, which is lower than the deposition temperature used with DCS but higher than that with Si₂H₆. Among the precursors—DCS, Si₂H₆, and SiH₄—the issue of high surface roughness-induced voids is relatively lower with the SiH₄-based precursor compared to the DCS-based precursor. Additionally, the surface migration ability of the SiH₄-based precursor is the best among the three. Therefore, taking into account both the formation of seams due to surface migration ability and the formation of voids due to surface roughness, some embodiments of the present disclosure use SiH₄ as the precursor for filling the deep trench 28 with polysilicon. However, the multi-round deposition-anneal technique for forming the semiconductor plug structure (e.g., a polysilicon plug) in the deep trench 28, which will be described later, is not limited to the usage of SiH₄-based precursor.

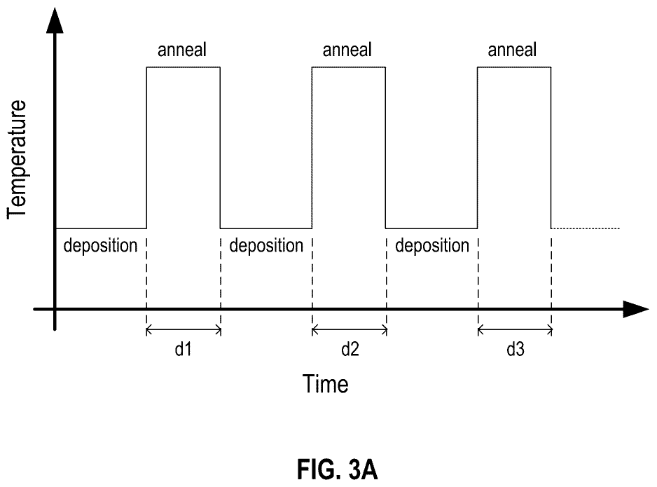

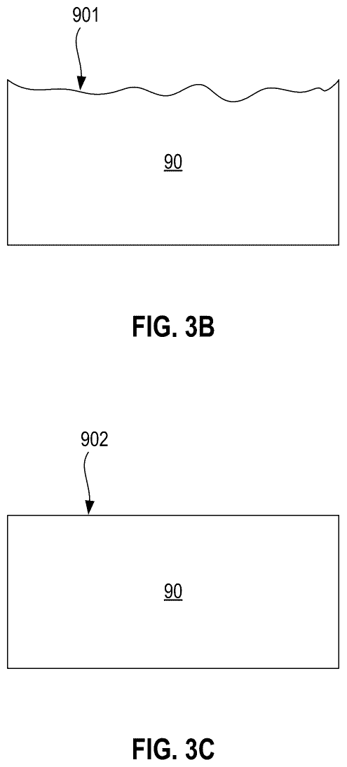

In case of there is a seam formed in the structure in the deep trench 28, in some embodiments, referring to FIG. 3A, and 4A to 4H, the deposition process can be adjusted into a plurality of rounds of deposition-anneal operations to improve the trench-filled capability of the polysilicon.

For instance, referring to the operation 103 in FIG. 1, the trench is filled with a polysilicon material. As illustrated in FIG. 3A, which is a graph showing the changes in time and temperature during the trench filling process. Referring to FIGS. 1, 2E, and 3A, the trench can be filled with polysilicon material by performing a plurality of rounds of deposition-anneal operations, where each round includes depositing the polysilicon material in the trench under a deposition temperature and annealing the polysilicon material under an annealing temperature. That is, the deposition process and the annealing process are performed alternatively. Once a thin polysilicon layer is formed, the deposition process is paused, and the annealing process is initiated for a certain duration to “reflow” the surface portion of the thin polysilicon layer. In some embodiments, a deposition temperature is less than 800° C. In some embodiments, the deposition temperature is in a range from about 650° C. to about 750° C., for example, at about 700° C.; and a depositing pressure is in a range from about 8 torr to about 12 torr, for example, as about 10 torr, in forming the thin polysilicon layer.

To be more detailed, the annealing process implemented after forming the thin polysilicon layer may smooth the surface thereof. When polysilicon material undergoes annealing in the LPCVD process, a transformation may occur within the material's structure and properties. In some embodiments, an anneal temperature is greater than 800° C. In some embodiments, the annealing temperature is in a range from about 800° C. to about 1,000° C., for example, at about 850° C., which may induce changes in its crystallinity, electrical behavior, and mechanical integrity. These changes may improve the overall performance of polysilicon in various semiconductor applications, wherein the change of surface roughness may greatly help in alleviating the seam issue in the polysilicon plug.

That is, in the aspect of surface roughness, the annealing process may promote surface smoothing by allowing atoms to migrate and settle into a more stable and even configuration. Referring to the example shown in FIGS. 3B and 3C, a silicon material 90 (e.g., polysilicon) may have a rough surface profile 901 after etched or deposited. However, after annealing, the surface roughness could change, resulting in a flat surface profile 902 due to the reflow mechanism of the silicon material 90. Therefore, the annealing process in some embodiments of the present disclosure may results in a smoother and more uniform surface of the thin polysilicon layer, and induce the opening of the deep trench 28 not be easily closed by the thin polysilicon layer. In some embodiments, an annealing duration (e.g., d1, d2, d3 in FIG. 3A) in each round of deposition-anneal operation is about 1 minute or 2-3 minutes. In some embodiments, an annealing pressure is in a range from about 4 torr to about 6 torr, for example, as about 5 torr, in annealing the thin polysilicon layer.

In some embodiments, the rounds of deposition-anneal operations in forming the polysilicon layer is less than about 5 or less than about 10. In some embodiments, the deposition-anneal operations in forming the polysilicon layer is at least 3, which means the polysilicon layer may be composed of at least three thin polysilicon layers, and each of the thin polysilicon layer are annealed after the formation of the thin polysilicon layer.

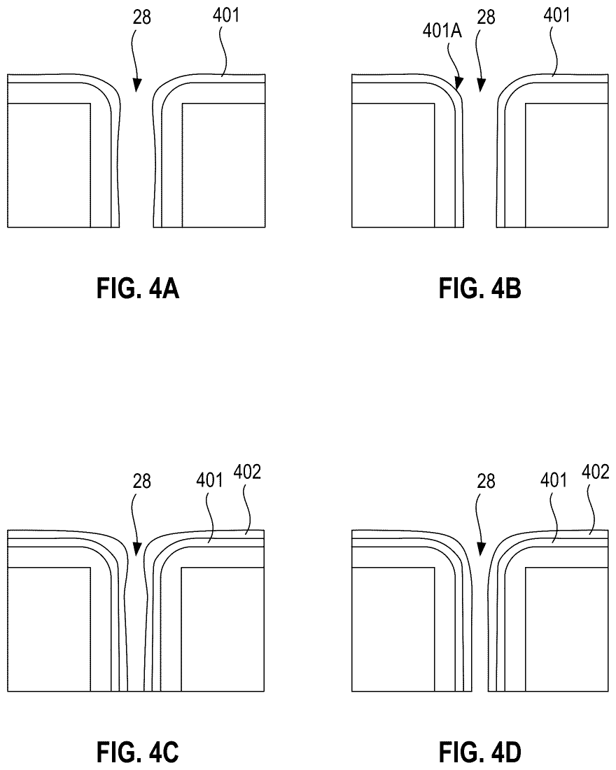

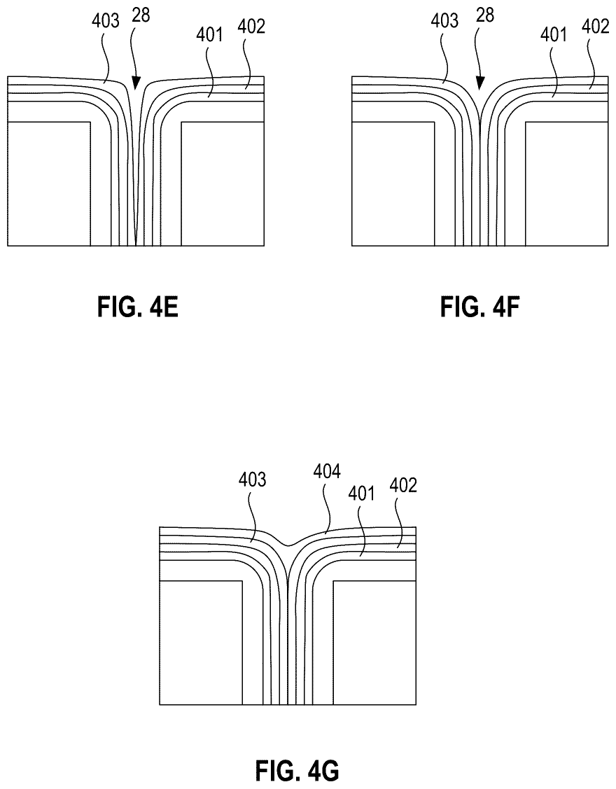

Referring to FIGS. 4A to 4F, for example, as shown in FIG. 4A, a first thin polysilicon layer 401 can be formed in the deep trench 28, wherein a thickness of the first thin polysilicon layer 401 is about 200 nm. The deposition temperature is about 700° C. and the deposition pressure at about 10 torr when using SiH₄-based precursor. Referring to FIG. 4B, the first polysilicon layer 401 is annealed for about at least 1 minute, or 2-3 minutes, under the annealing temperature at about 850° C. and the annealing pressure at about 5 torr. The surface 401A of the first thin polysilicon layer 401 can be smoothed due to surface migration enhanced in the annealing temperature, and the opening of the deep trench 28 after forming the first thin polysilicon layer 401 is slightly increased after the annealing process. Then, by repeating the depositing operation and the annealing operation, such as a second thin polysilicon layer 402 and a third thin polysilicon layer 403 are formed subsequently in FIGS. 4C and 4E, and the thickness, the deposition temperature, the deposition pressure, and the precursor used are substantially identical to those of forming the first thin polysilicon layer 401. Also, as shown in FIGS. 4D and 4F, and 4H, the second thin polysilicon layer 402 and the third thin polysilicon layer 403 are annealed once these thin polysilicon layers are formed. The annealing duration, the annealing temperature, and the annealing pressure in annealing these third thin polysilicon layers can be substantially identical to those of annealing the first thin polysilicon layer 401. As illustrated in FIG. 4F, the rounds of deposition-anneal operations can be terminated when the polysilicon material (e.g., the stack of the first, the second, and the third, thin polysilicon layers 401-403) closes an upper portion of the deep trench 28.

In some embodiments, since the stack of the thin polysilicon layers may have a deep concave profile directly over the deep trench 28, referring to FIG. 4G, a cap polysilicon layer 404 can be formed over the third thin polysilicon layer 403 to alleviate uneven profile of the stack of these polysilicon layers. The cap polysilicon layer 404 can be used to prevent the concave profile of the stack of the thin polysilicon layers is left after the subsequent CMP operation. In some embodiments, a thickness of the cap polysilicon layer 404 is about 400 nm.

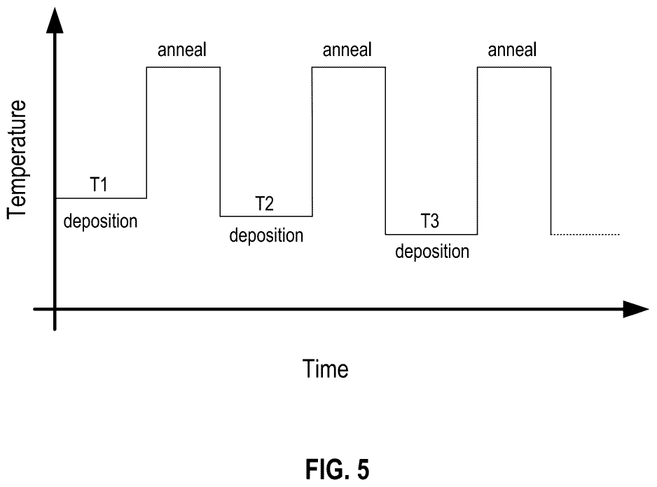

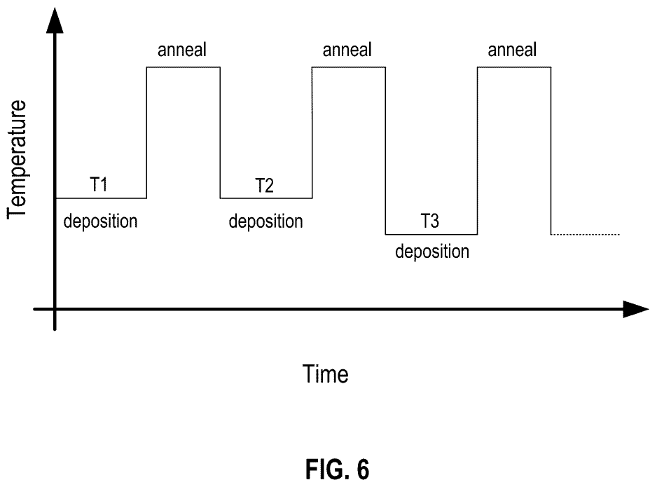

In some embodiments, as shown in FIG. 5, which is another graph showing the changes in time and temperature during the trench filling process, the deposition temperature decreases gradually across different rounds of deposition-anneal operations. Since a lower deposition temperature of the polysilicon material may result in a thin polysilicon layer with smaller grain size, lowering the deposition temperature in the later rounds of the deposition-anneal operation can prevent large grain sizes from closing the trench opening too easily. The rationale for considering a lower deposition temperature in the final rounds of the deposition-anneal process is that the opening of the deep trench 28 becomes quite narrow, and larger polysilicon grains could pose more of a challenged at that time. As the embodiment shown in FIG. 5, the deposition temperature decreases gradually across different rounds of deposition-anneal operations. For instance, within the three rounds of deposition-anneal operations shown in the figure, a first deposition temperature T1 in a first round is greater than a second deposition temperature T2 in a second round, and the second deposition temperature T2 in the second round is greater than a third deposition temperature T3 in a third round. Alternatively, as the embodiment shown in FIG. 6, the deposition temperature decreases gradually in the deposition-anneal operations, where the first few rounds can have the same deposition temperature. For instance, within the three rounds of deposition-anneal operations shown in the figure, the first deposition temperature T1 in the first round is substantially identical to the second deposition temperature T2 in the second round, and the second deposition temperature T2 in the second round is greater than a third deposition temperature T3 in a third round. As aforementioned, the deposition temperature may in a range from about 650° C. to about 750° C., and therefore in some embodiments, the deposition temperature in the last round of the deposition-anneal operation is about 650° C.

In some embodiments, the surface migration capability of the polysilicon can be further enhanced by forming one or more SiGe layers additionally during the plurality of rounds of deposition-anneal operations. Considering that the self-diffusion feature of SiGe may improve its surface roughness, and therefore in some scenarios where the seam issue is hard to overcome (e.g. a higher aspect ratio of the deep trench), the additional SiGe layer(s) may provide benefits other than merely uses the multi-round deposition-anneal technique.

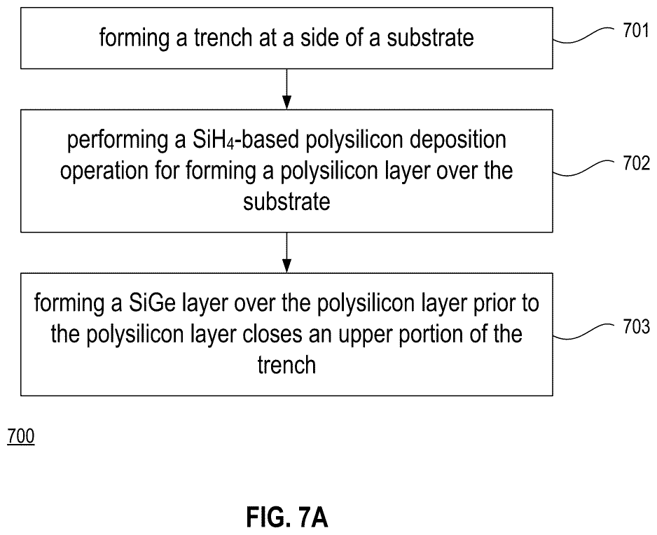

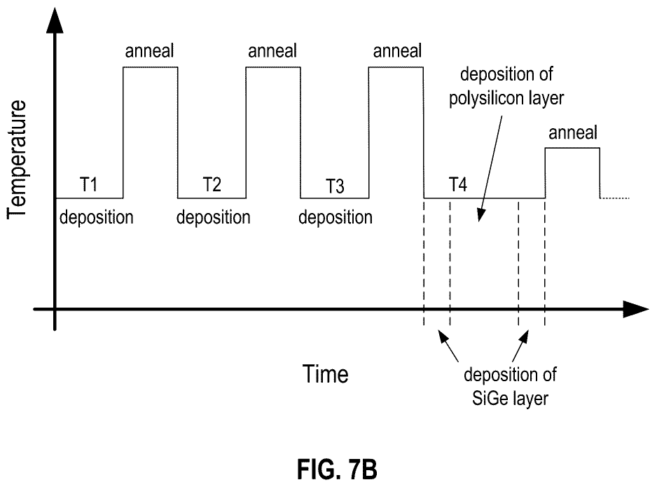

Referring to FIGS. 7A and 7B, which illustrate a flow diagram illustrating a method 700 including operations 701-703 for manufacturing a semiconductor plug structure in a substrate structure, and a graph shows the changes in time and temperature during the trench filling process, where these embodiments include the deposition of a SiGe layer. In some embodiments, one or more SiGe layers can be formed in the final round of deposition-anneal operations. For instance, a first SiGe layer can be formed after the third annealing process (i.e., at the start of the fourth round of deposition-anneal operations). The first SiGe layer can be a 10% poly-SiGe layer, composed of 10% germanium (Ge) and 90% polysilicon. Moreover, in some examples, a second SiGe layer can be formed after the deposition of the fourth thin polysilicon layer (i.e., before the fourth annealing process). The material of the second SiGe layer can be identical to that of the first SiGe layer.

Within the plurality rounds of deposition-anneal operations shown in the embodiment in FIG. 7A, the first, the second, and the third deposition temperatures T1-T3 are substantially identical to a fourth deposition temperature T4 in depositing the SiGe layers. In some embodiments, a deposition temperature in depositing the SiGe layers is less than 800° C. In some embodiments, the deposition temperature is in a range from about 650° C. to about 750° C., for example, at about 700° C.; and a depositing pressure in depositing the SiGe layers is in a range from about 8 torr to about 12 torr, for example, as about 10 torr. In some embodiments, the thickness of the SiGe layer is about 10 nm. Since the formation of the one or more SiGe layers occurs either immediately before or after the formation of the final thin polysilicon layer, in some embodiments, the annealing temperature used to anneal the last thin polysilicon layer is lower than the annealing temperature used for the other thin polysilicon layers. For instance, the anneal temperature of the SiGe layers and the last thin polysilicon layer can lower than about 800° C., while an annealing pressure in annealing the SiGe layers and the last thin polysilicon layer (e.g., identical to the depositing pressure in depositing the SiGe layers, such as in a range from about 8 torr to about 12 torr) can be greater than that in annealing the other thin polysilicon layer (e.g., in a range from about 4 torr to about 6 torr, as previously mentioned).

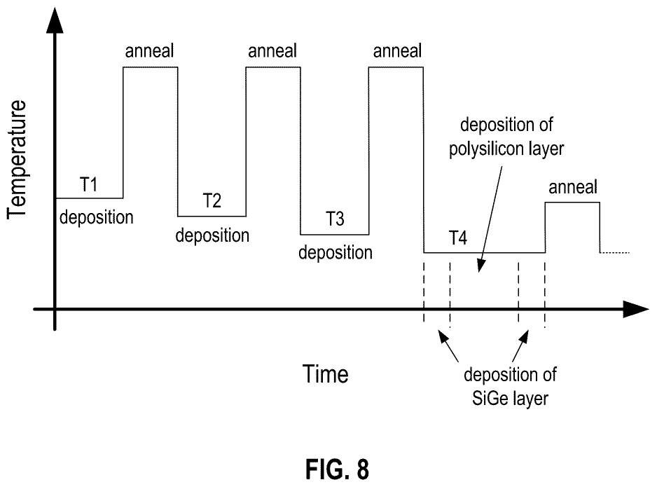

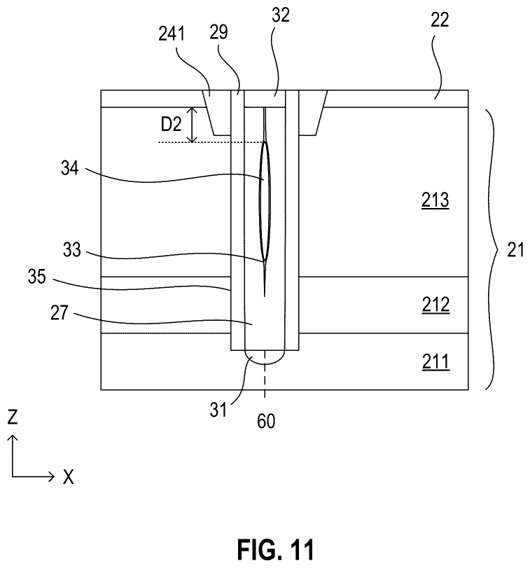

Referring to FIG. 8, in some embodiments, in case of one or more SiGe layers (shown in FIG. 11) are formed in the final round of deposition-anneal operations, the deposition temperature still can decrease gradually across different rounds of deposition-anneal operations (e.g., T1≥T2>T3) for forming the thin polysilicon layer with smaller grain size. For instance, at least the deposition temperature (e.g., the fourth deposition temperature T4) in the final round of deposition-anneal operations is the lowest.

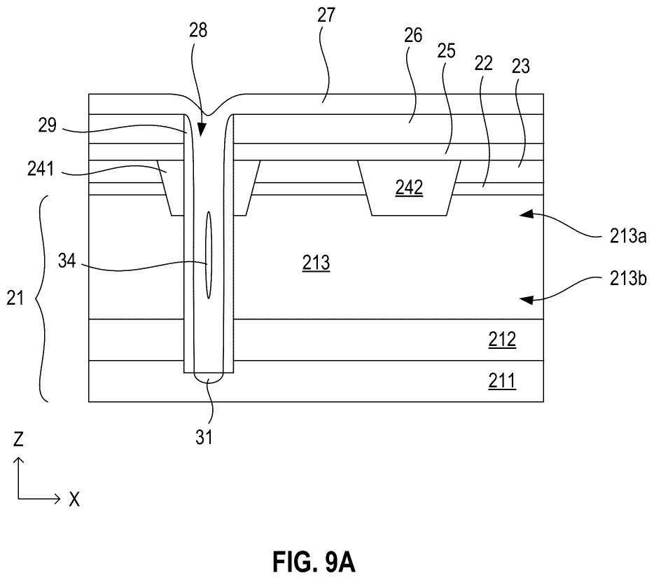

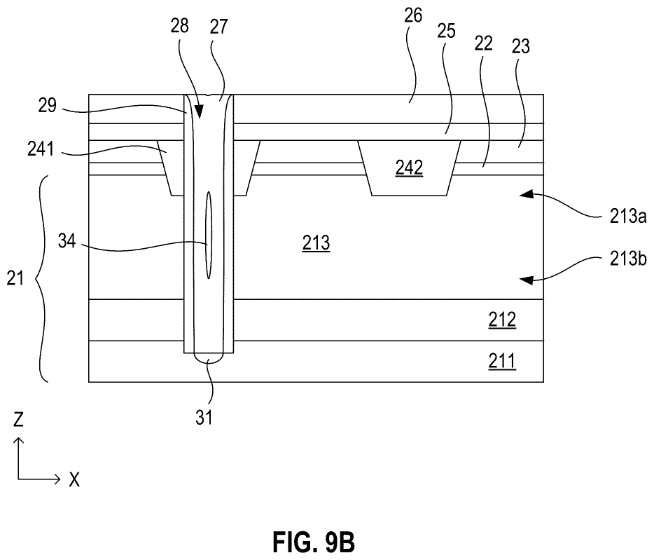

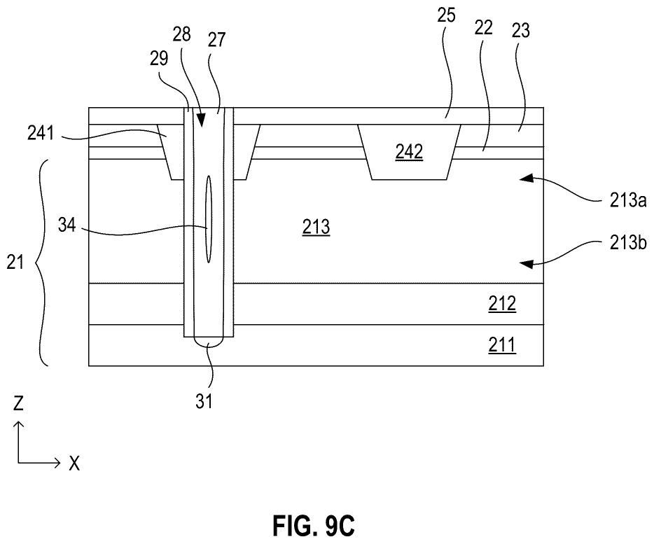

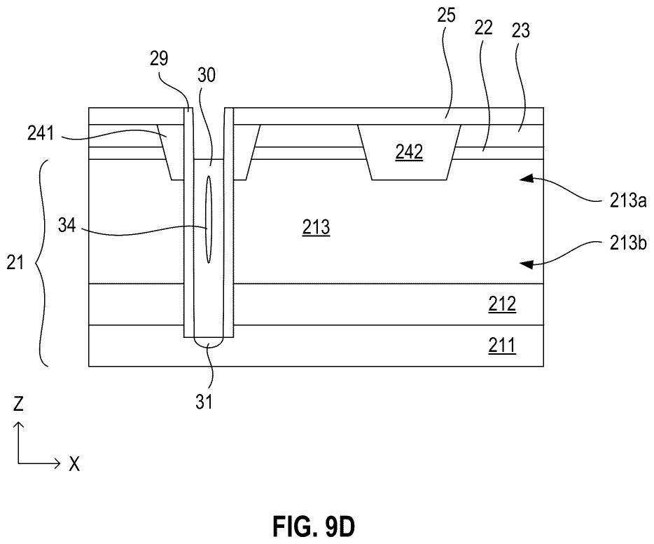

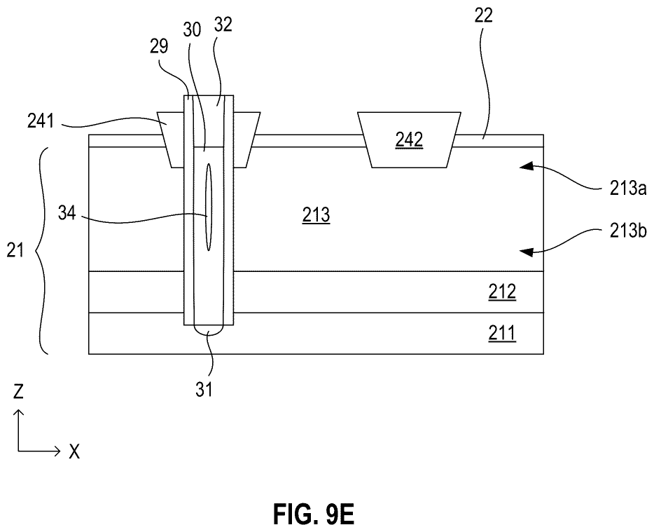

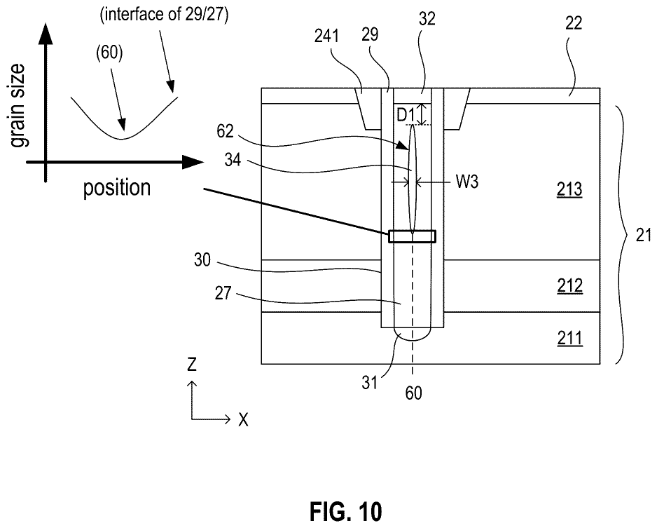

In some embodiments, after filling the deep trench with polysilicon material, a first planarization process can be performed to remove a portion of the polysilicon material in the upper portion of the deep trench. Referring to FIGS. 9A and 9B, the first planarization process is a polysilicon CMP which is performed to remove an upper portion of the polysilicon material 27. The first planarization process may be stop at an upper end of the insulating material layer 29 is exposed. Next, referring to FIG. 9C, a second planarization process can be performed to remove the dielectric layer 26. The second planarization process may be stop at an upper surface of the second nitride layer 25.

Referring to FIG. 9D, in some embodiments, the polysilicon material 27 (see FIG. 9C) in the deep trench 28 (see FIG. 9C) is etched back using dry etching to form a semiconductor plug structure 30. In some embodiments, the etch of the polysilicon material 27 in the deep trench 28 can be performed using an etchant for polysilicon or other suitable etchants. The etch-back operation is performed to align an upper surface of the polysilicon material in the deep trench 28 with an upper surface of an oxide definition (OD) layer, such as an upper surface of the upper semiconductor layer 213. That is, the etch back operation can be performed until the top surface of the etched polysilicon material is located at a substantially same level as the top surface of the upper semiconductor layer 213. In some embodiments, the top surface of the etched polysilicon material 27 may be located at a level slightly higher or lower than the top surface of the upper semiconductor layer 213, and a height difference between the top surface of the etched polysilicon material 27 and the top surface of the upper semiconductor layer 213 may range from 0 Å to about 300 Å.

Referring to FIG. 9E, in some embodiments, a contact structure 32 is formed over the upper surface the etched polysilicon material 27. Since the contact structure 32 is formed on the etched polysilicon material 27, a bottom of the contact structure 32 is substantially leveled with the top surface of the upper semiconductor layer 213. In some embodiments, the contact structure 32 can be formed by depositing conductive material over the etched polysilicon material 27, and a patterned mask (not shown) can be used. In some embodiments, prior to forming the contact structure 32, the first nitride layer 23 and the second nitride layer 25 over the upper semiconductor layer 213 are removed by etchant. For example, phosphoric acid or other suitable etchants. In some embodiments, in case of the etched polysilicon material 27 includes a seam structure 34 inside, by using the method disclosed in the present disclosure, a distance between an upper end of the seam structure 34 and upper surface of the etched polysilicon material 27 is greater than about 500 nm.

Referring to FIG. 10, which illustrates a semiconductor structure manufactured by the method disclosed in some embodiments of the present disclosure. As shown in FIG. 10, the semiconductor structure includes a substrate structure (e.g., the semiconductor substrate 21), a semiconductor plug structure 30 (e.g. the polysilicon material 27) in the substrate structure, and insulating materials 29. In some embodiments, sidewalls of the semiconductor plug 30 is separated from the semiconductor substrate 21 by the insulating materials 29. Other than the semiconductor plug structure 30, the structures in the substrate structure may refer to the structure features previously shown in FIGS. 2A to 2E and are omitted for the sake of brevity. In some embodiments, the semiconductor plug structure 30 includes a central line 60 substantially parallel to or identical to an axial of the semiconductor plug structure 30. An average grain size of the polysilicon material in the semiconductor plug structure 30 in proximity to the central line 60 is smaller than an average grain size of a polysilicon material in the semiconductor plug structure 30 in proximity to a side of the semiconductor plug structure 30 (i.e., the interface of the polysilicon material 27 and the insulating material layer 29). In other words, in some embodiments, an average grain size of the polysilicon material in the semiconductor plug structure 30 can substantially symmetric to the central line 60 from a cross-section view perspective. The trend of the average grain size can be controlled by adjusting the annealing temperature in the later rounds of forming the stack of the polysilicon material 27 using a multi-round deposition-anneal technique, as the polysilicon material deposited in the later rounds may have a smaller grain size at a lower annealing temperature.

In some embodiments, the semiconductor plug structure 30 includes the seam structure 34 at the central line 60. In some embodiments, a distance D1 between an upper end of the seam structure 34 and an upper surface of the semiconductor plug structure 30 (which can be in line with an upper surface of the polysilicon material 27) is substantially greater than about 800 nm. Such distance can be called a seam depth, and the seam depth as deep in these embodiments can be achieved by using precursors such as SiH₄-based precursor, for example, in depositing the polysilicon material and using the multi-round deposition-anneal technique (i.e., including in-situ cyclic annealing). In some embodiments, a surface roughness of the polysilicon material 27 at the seam structure 34 (e.g., the surface roughness of an inner surface 62 in the seam structure 34) is less than about 30 nm. In some embodiments, a width W3 of the seam structure 34 is less than about 70 nm.

In some embodiments, a top surface of the contact structure 32 is coplanar to a top surface of the pad oxide layer 22 and a top surface of the first STI structure 241 since a planarization process is performed after forming the contact structure 32 and before performing other deposition operations.

Referring to FIG. 11, which illustrates a semiconductor structure manufactured by the method disclosed in some embodiments of the present disclosure. As shown in FIG. 11, the semiconductor structure includes a substrate structure and a semiconductor plug structure in the substrate structure. Other than a semiconductor plug structure 35, the structures in the substrate structure may refer to the structure features previously shown in FIGS. 2A to 2E and are omitted for the sake of brevity. In some embodiments, the semiconductor plug structure 35 also includes the central line 60 substantially parallel to or identical to the axial of the semiconductor plug structure 35. Moreover, within the semiconductor plug structure 35, it may further include one or more SiGe layer 33 substantially symmetric to the central line 60 from a cross-section view perspective. In some embodiments, a Ge concentration in the semiconductor plug structure 35 with a conductive material penetrated thereof is substantially symmetric to the central line 60 of the semiconductor plug structure 35 from a cross-section view perspective. In some embodiments, a thickness of the SiGe layer 33 is about 10 nm. In some embodiments, the SiGe layer 33 is formed in the final round of deposition-anneal operations to enhance the surface migration capability of the polysilicon material. In some embodiments, a distance D2 between an upper end of the seam structure 34 and an upper surface of the semiconductor plug structure 35 (i.e., the seam depth) is substantially greater than about 1,000 nm since the SiGe-enhanced technique is applied.

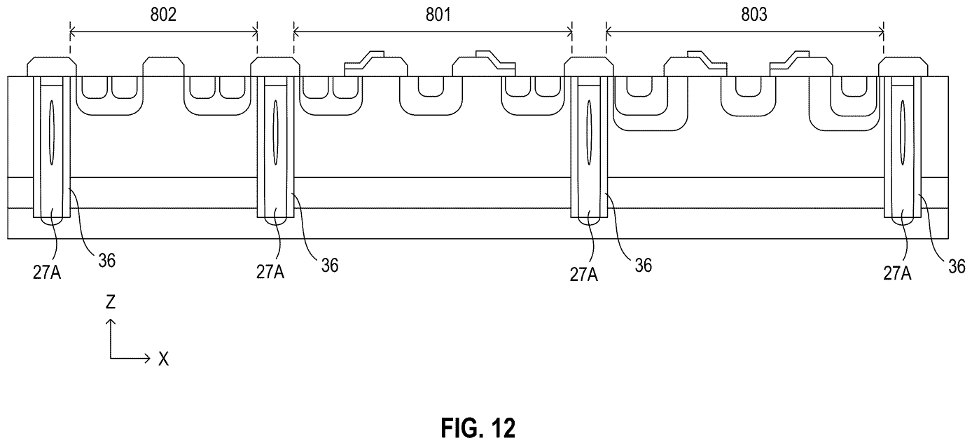

Referring to FIG. 12, in some embodiments, the semiconductor plug structure disclosed in the present disclosure can be applied in a BCD device 80. The BCD device 80 includes a bipolar device 801, a CMOS device 802, and a DMOS device 803, where these devices are laterally isolated by DTI structures 36 (i.e., the insulating materials 29). In some embodiments, the BCD device 80 can be a SOI-based BCD device. In some embodiments, these kinds of high-voltage SOI-based BCD device may use the semiconductor plug 27A structure in the DTI structures 36 for grounding, such as the as the polysilicon plug 27A (i.e., the polysilicon material 27 shown in FIG. 11, and 12) for grounding. By using the method for manufacturing the semiconductor plug structure disclosed in some embodiments of the present disclosure, the issue of “contact open” caused by unwanted seams is mitigated.

Overall, some embodiments of the present disclosure provide a method that utilizes a multi-round deposition-annealing technique, or incorporates a SiGe-enhanced approach to improve the surface migration capability of polysilicon material in forming deep trench isolation structures. Unlike other trench-filling processes where oxide materials are used to fill the trench or deep trench, polysilicon is well-suited for the multi-round deposition-annealing technique. Additionally, the potential “contact open” issue caused by unwanted seams in the conductive material within the deep trench isolation structure can be mitigated, as any seam that forms can occur at a much deeper level (if a seam forms at all).

In one exemplary aspect, a method for manufacturing a semiconductor plug structure in a semiconductor structure is provided. The method includes the operations as follows. A substrate is received. A trench is formed at a side of the substrate. The trench is filled with a polysilicon material. Rounds of deposition-anneal operations are terminated when the polysilicon material closes an upper portion of the trench. Filling the trench includes performing a plurality of rounds of deposition-anneal operations, and each round including depositing the polysilicon material in the trench under a deposition temperature and annealing the polysilicon material under an annealing temperature.

In another exemplary aspect, a method for manufacturing a semiconductor plug structure in a substrate structure is provided. The method includes the operations as follows. A trench at a side of a substrate is formed. A polysilicon deposition operation is performed for forming a polysilicon layer over the substrate. A SiGe layer is formed over the polysilicon layer prior to the polysilicon layer closes an upper portion of the trench.

In yet another exemplary aspect, a semiconductor structure is provided. The semiconductor structure includes a substrate structure and a semiconductor plug structure in the substrate structure. The semiconductor plug structure comprises a central line substantially parallel to an axial of semiconductor plug structure, wherein an average grain size of a polysilicon material in the semiconductor plug structure in proximity to the central line is smaller than an average grain size of a polysilicon material in the semiconductor plug structure in proximity to a side of the semiconductor plug structure.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor plug structure in a semiconductor structure, the method comprising:
receiving a substrate;
forming a trench at a side of the substrate; and
filling the trench with a polysilicon material, comprising:
performing a plurality of rounds of deposition-anneal operations, each round comprising:
depositing the polysilicon material in the trench under a deposition temperature; and
annealing the polysilicon material under an annealing temperature; and
terminating the rounds of deposition-anneal operations when the polysilicon material closes an upper portion of the trench.

2. The method of claim 1, further comprising:
forming a cap polysilicon layer over the polysilicon material after the polysilicon material closes the upper portion of the trench, wherein a thickness of the cap polysilicon layer is greater than a thickness of the polysilicon material deposited in each round of deposition-anneal operation.

3. The method of claim 1, wherein the deposition temperature is in a range from about 650° C. to about 750° C.

4. The method of claim 1, wherein an annealing pressure in annealing the polysilicon material is lower than a depositing pressure in depositing the polysilicon material in each round of deposition-anneal operations.

5. The method of claim 1, wherein a precursor in the depositing the polysilicon material in the trench comprises SiH₄.

6. The method of claim 1, wherein a thickness of the upper portion of the trench substantially greater than about 800 nm.

7. The method of claim 1, further comprising:
performing a planarization process to remove a portion of the polysilicon material;
etch-back the polysilicon material in the trench to align an upper surface of the polysilicon material in the trench with an upper surface of an oxide definition (OD) layer; and
forming a contact structure over the upper surface of the polysilicon material in the trench.

8. The method of claim 7, wherein the polysilicon material in the trench comprises a seam structure, a distance between an upper end of the seam structure and the upper surface of the polysilicon material in the trench is greater than about 500 nm.

9. The method of claim 1, wherein the deposition temperature decreases gradually across different rounds of deposition-anneal operations.

10. A method for manufacturing a semiconductor plug structure in a substrate structure, the method comprising:
forming a trench at a side of a substrate;
performing a polysilicon deposition operation for forming a polysilicon layer over the substrate; and
forming a SiGe layer over the polysilicon layer prior to the polysilicon layer closes an upper portion of the trench.

11. The method of claim 10, wherein the polysilicon deposition operation is a SiH₄-based polysilicon deposition operation, a deposition temperature is in a range from about 650° C. to about 750° C., and a depositing pressure is in a range from about 8 torr to about 12 torr in forming the polysilicon layer.

12. The method of claim 10, wherein forming the polysilicon layer over the substrate comprises performing a plurality of rounds of deposition-anneal operations, each round comprising:
depositing a polysilicon material in the trench under a deposition temperature; and
annealing the polysilicon material under an annealing temperature.

13. The method of claim 12, wherein the SiGe layer is formed during a final round of the deposition-anneal operations.

14. The method of claim 12, wherein an annealing duration in each round of deposition-anneal operation is at least 1 minute.

15. The method of claim 12, wherein the rounds of deposition-anneal operations in forming the polysilicon layer is less than about 10.

16. A semiconductor structure, comprising:
a substrate structure; and
a semiconductor plug structure in the substrate structure, the semiconductor plug structure comprises a central line substantially parallel to an axial of a DTI structure, wherein an average grain size of a polysilicon material in the semiconductor plug structure in proximity to the central line is smaller than an average grain size of a polysilicon material in the semiconductor plug structure in proximity to a side of the semiconductor plug structure.

17. The semiconductor structure of claim 16, wherein the semiconductor plug structure comprises a seam at the central line, wherein a distance between an upper end of the seam and an upper surface of the semiconductor plug structure is substantially greater than about 800 nm.

18. The semiconductor structure of claim 17, wherein a surface roughness of the polysilicon material at the seam is less than about 30 nm.

19. The semiconductor structure of claim 17, wherein a width of the seam is less than about 70 nm.

20. The semiconductor structure of claim 16, wherein the semiconductor plug structure further comprises at least a SiGe layer substantially symmetric to the central line from a cross-section view perspective.
